(19) United States
(12) Patent Application Publication
(10) Pub. No.: US 2004/0191556 A1
(43) Pub. Date: Sep. 30, 2004

(54) Shape memory device having two-way cyclical shape memory effect due to compositional gradient and method of manufacture

(76) Inventor: Peter A. Jardine, Thousand Oaks, CA (US)

Correspondence Address: OSTROLENK FABER GERB & SOFFEN, 1180 AVENUE OF THE AMERICAS, NEW YORK, NY, 100368403

(21) Appl. No.: 10/734,812

(22) Filed: Dec. 11, 2003

Related U.S. Application Data
(63) Continuation-in-part of application No. 10/282,276, filed on Oct. 28, 2002, now Pat. No. 6,689,486.
Application No. 10/282,276 is a continuation of application No. 09/795,555, filed on Feb. 28, 2001, now abandoned.
(60) Provisional application No. 60/185,841, filed on Feb. 29, 2000.

(51) Int. Cl. C23C 14/32; B32B 15/00

(52) U.S. Cl. 428/610; 428/938; 428/660; 204/192.15; 337/85

(57) ABSTRACT

A comparatively high vacuum pressure method of manufacturing two-way shape memory effect devices produces devices having a compositional gradient through the thickness of a film of shape memory alloy. The shape memory alloy film exhibits two-way shape memory effect, which is useful for fabricating cyclical actuating devices without need of a biasing mechanism. Examples of shape memory alloys include Ni:Ti-, Au:Cd-, Fe:Mn:Si- and Cu:Ni:Al-based binary, ternary and higher order alloys. Three-dimensional devices may be mass produced using the shape memory alloy and process.

### RELATED APPLICATIONS

This application is a continuation-in-part of application Ser. No. 10/282,276 filed Oct. 28, 2002, which was a continuation of application Ser. No. 09/795,555 (now abandoned) filed Feb. 28, 2001, which claims the benefit of U.S. Provisional Application No. 60/185,841 filed Feb. 29, 2000 in the names of Ken K. Ho, Gregory P. Carman and Peter A. Jardine, entitled “Bimorphic Compositionally-Graded, Sputter-Deposited, Thin Film Shape Memory Device,” the disclosures of each of the foregoing applications being incorporated in its entirety herein.

### FIELD OF THE INVENTION

The present invention relates to a shape memory device that exhibits two-way, cyclical shape change, and the process for producing the same. Specifically, films of shape memory alloys, such as Au:Cd and Au:Cd based ternary alloys, Fe:Mn:Si-based, Cu:Ni:Al-based and Cu:Zn:Al-based ternary, quaternary and higher alloys.

### BACKGROUND OF THE INVENTION

NiTi is a shape memory alloy (SMA) that is capable of recovering strains on the order of 10%. This effect, referred to as the shape memory effect (SME), occurs when the material undergoes a phase transformation from the low temperature martensitic phase to the high temperature austenitic phase. In the martensitic phase the material is deformed by preferential alignment of twins. Unlike permanent deformations associated with dislocations, deformation due to twinning is fully recoverable when heated to the austenite phase.

A difficulty in using thin film SMA is that the deposited films exhibit the one way shape memory effect (SME) only. An SME material recovers its original shape after heating to the austenite phase but does not revert back to its deformed state when cooled. In order to achieve cyclic actuation, a biasing force such as a spring is necessary to deform the material when in the martensite phase. Implementing a bias force on thin film structures present significant manufacturing obstacles, an additional challenge for using thin film SME in MEMS actuators.

The first work to incorporate thin film NiTi in devices used a micro-machining process developed by Walker et al. in 1990 [J. A. Walker, K. J. Gabriel, and M. Mehregany, Sens. Actuators, Vols. A21-A23, p. 243, 1990]. Walker et al. used a wet chemical etchant (HF+HN03+H20) to pattern a free standing serpentine NiTi spring. The structures were curled when released and uncurled when heated, they attributed this to the shape memory effect. However, the films were amorphous as deposited. In 1990 Bush and Johnson at the TiNi Alloy Company showed the first definitive evidence of SME in NiTi films [J. D. Busch, A. D. Johnson, et al., “Shape-memory properties in Ni—Ti sputter deposited film”, J. Appl. Phy., Vol. 68, p. 6224, 1990]. Using a single target (50/50 atm % NiTi), with a DC magnetron sputtering system they pre-sputtered for 3 hours. Sputtering of the film was performed with a P_{Ar}=0.75 mTorr, V=450V, I=0.5 A, and a target substrate distance of 2.25 inches was used. The as-deposited film was shown by XRD to be amorphous and, after vacuum annealing at 550° C. for 30 minutes, exhibited the SME although transformation temperatures were 100° C. lower than the target material.

To achieve a cyclical, two-way effect, a biasing force is required to reshape the NiTi when cooled. Kuribayashi introduced a biasing force by tailoring precipitates in his films such that there were compressive and tensile stresses on opposite sides of his film [K. Kuribayashi, T. Taniguchi, M. Yositake, and S. Ogawa, “Micron sized arm using reversible TiNi alloy tin film actuators”, Mat. Res. Soc. Symp. Pro., vol. 276, p. 167, 1992]. The film curled when in the martensitic phase and when heated to the austenite phase flattened because the higher modulus overcomes the residual stresses. The fabrication process required complicated heat treatments. The stability of these precipitates can degrade over numerous thermal cycles.

Thin film TiNi actuators are well suited for MEMS devices because of their large work energy densities. However, the difficulties associated with depositing this material has limited its access by the MEMS community. To address this issue, researchers focused on deposition, heat treatments, and thermomechanical characterization of the film [J. D. Busch, M. H. Berkson, and A. D. Johnson, Phase transformations in sputtered NiTi film: effects of heat treatment and precipitates, Mat. Res. Soc. Symp. Proc., vol. 230, p. 91, 1992; D. S. Grummon and T. J. Pence, “Thermotractive titanium-nickel thin films for microelectromechanical systems and active composites”, Mat. Res. Soc. Symp. Pro., Vol. 459, p. 331, 1997; Q. Su, S. Z. Hua and M. Wuttig, “Martensitic transformation in NiTi films”, J. of Alloys and Compound, vol. 211, p. 460, 1994; S. Miyazaki, et al., “Shape memory characteristics of sputter-deposited Ti—Ni base thin films”, SPIE, vol. 2441, p. 156, 1995; and A. Ishida, A. Takei, M. Sato and S. Miyazaki, “Shape memory behavior of Ti—Ni thin films annealed at various temperatures”, Mat. Res. Soc. Symp. Proc., vol. 360, p. 381, 1995, 11-15]. Few researchers developed actual micro-devices.

The TiNi Alloy Co. has a working microvalve it markets, which closes using a bias mass and opens when the thin film NiTi ligaments are heated [C. A. Ray, C. L. Sloan, A. D. Johnson, J. D. Busch, B. R. Petty, Mat. Res. Soc. Symp. Proc. 276, 161 (1992)]. Krulevitch et al. fabricated a 900 μm long, 380 μm wide, and 200 μm tall microgripper from 5 μm thick NiTi—Cu film, as well as a functioning microvalve [P. Krulevitch, et al., supra]. Bernard et al. fabricated a micro-pump from NiTi film using two designs: polyimide as the biased actuator in one and a complementary NiTi actuator in the other [W. L. Bernard, H. Kahn, A. H. Heuer and M. A. Huff, “Thin film shape memory alloy actuated micropumps”, J. of Microelectromechanical Systems, vol. 7, no. 2, 1998]. Kuribayashi et al. used TiNi films to actuate a microrobotic manipulator [K. Kuribayashi, S. Shimizu, T. Nishinohara and T. Taniguchi, “Trial fabrication of micron sized arm using reversible TiNi alloy thin film actuators”, Proceedings International Conf. On Intel. Robots and Sys., Yokohama, Japan, p. 1697, 1993]. While the potential applications for SMA MEMS are large, the difficulties with fabricating quality material and achieving the two-way effect is preventing wide spread use of this actuator material.

NiTi films with transformation temperatures above room temperature are difficult to manufacture. Sputtering directly from a 50/50 at. % NiTi target results in films which dramatically lowered transformation temperatures, prohibiting its use as an actuator [J. D. Busch, et al., supra]. This is caused by the fact that NiTi alloys are strongly dependent on composition, annealing temperatures, aging time, and sputtering parameters [S. Miyazaki, et al., “Effect of heat treatment on deformation behavior associated with R-phase and martensitic transformations in Ti—Ni thin film”, Trans. Mat. Res. Soc. Jpn., Vol. 18B, p. 1041, 1994; A. Ishida, M. Sato, A. Takei and S. Miyazaki, “Effect of heat treatment on shape memory behavior of Ti-rich Ti—Ni thin films”, Materials Transactions, JIM, vol. 36, p. 1349, 1995; and A. Peter Jardine, “Deposition parameters for sputter-deposited thin film TiNi”, Mat. Res. Soc. Symp. Proc., vol. 360, p. 293, 1995]. Of these factors, alloy compositions is the most critical.

NiTi alloys and other shape memory alloys are strongly dependent on composition, annealing temperatures, aging time, and sputtering parameters. Composition is the most critical sputter parameter. Typically, small changes in composition occur during sputtering because titanium readily reacts with other materials. FIG. 1 shows the dependence of transformation temperature on Ni—Ti stoichiometry, a shift in composition of as little as 1 atm % can alter transformation temperatures by 100° C. [T. W. Duereig, K. N. Melton, D. Stockel and C. M. Wayman, Engineering Aspects of Shape Memory Alloys, 1990]. Titanium is typically used to getter materials, and is often used in vacuum systems to lower the vacuum by reacting with the gases and condensing. Miyazaki, et al., compensated for the titanium loss by placing titanium plates on top of the alloy target, thereby effectively altering the composition of the target [S. Miyazaki and K. Nomura, “Development of perfect shape memory effect in sputter-deposited Ti—Ni thin films”, Proceedings IEEE Microelectro Mechanical Sys., p. 176, 1994]. Wolf et al. similarly compensated with titanium foils [R. H. Wolf and A. H. Heuer, “TiNi (Shape Memory) Films on Silicon for MEMS Applications”, J. of Microelectromechanical Sys., vol. 4, no. 4, p. 206, 1995], and A. Gyobu et al. also recently sputtered from a 50/50 NiTi target using titanium compensation [A. Gyobu, Y. Kawamura, H. Horikawa, and T. Saburi, “Martensitic transformations in sputter deposited shape memory Ti—Ni films”, Mat. Trans. JIM, vol. 37, no. 1-6, p. 697, 1996]. The other method of compensating for the titanium loss is to use a multigun co-sputtering system. For example, Krulevitch et al. used a DC magnetron system to sputter from individually powered Ni, Ti, and Cu targets [P. Krulevitch, A. P. Lee, P. B. Ramsey, et al., “Thin film shape memory alloy microactuators”, J. of Microelectromechanical Sys., vol. 5, No. 4, 1996].

A further complication is that the NiTi phase is very narrow at low temperatures. Slight shifts in the Ni:Ti stoichiometry can cause precipitate formation, and complicate the metallurgical heat treatment required to establish a desired transformation temperature. It would be advantageous to develop a simple approach that could produce a deposited film with composition similar to the target.

Thin film NiTi fabricated by sputtering offers a promising new material for solid state actuation in the MEMS field as well as new possibilities for medical devices, because of its large energy density (1 J/g) and large displacement (10% strain). Since NiTi SMA shape memory alloys are heat actuated, improved performance can be achieved at microscales. Frequencies of several hundred hertz can be achieved [J. Favalukis, A. S. Lavine, G. P. Carman, Proc. SPIE 3668, 617 (1999)]. Specifically, with a smaller mass and larger surface to volume ratio, heat transfer is substantially increased, power requirements are lowered, and large stresses and strains are achievable. These advantages make NiTi SMA a very promising actuation mechanism for microdevices.

Sputtering of NiTi thin film from a 50/50 at. % NiTi target produces films with transformation temperatures different from the target due to loss of titanium during sputtering. NiTi films with transformation temperatures above room temperature are difficult to manufacture. Sputtering processes typically produce films with reduced transformation temperatures (i.e. below room temperature), requiring artificial cooling to use as an actuator. Researchers have compensated for this, by placing Ti plates on the target to effectively alter the composition of the target, or to sputter off of a nonstoichiometric NiTi target.

A microscale actuator for active flow control could be implemented using the SME. In recent years the combined evolution of MEMS (microelectro-mechanical systems) technology and active materials has produced advancements that can make Active Flow Control (AFC) practice [C. M. Ho and Y. Tai, “Mems: Science and Technology,” Application of Microfabrication to Fluid Mechanics, FED V. 197, ASME 1994, pp. 39-49, 1994]. Active Flow Control (AFC) represents an advanced concept for reducing drag, controlling flow separation, improving flight control effectiveness, and manipulation of wake vortex interactions in aircraft systems. The AFC concept has been investigated for the last 30 years. The obstacle to its successfully implementation has been a lack of a compact rugged sensor-actuator technology.

Previously, it was difficult to sputter deposit NiTi films with transformation temperatures above 25° C. from a single unmodified 50/50 atm % NiTi target. The co-pending application discloses transformation temperatures above 25° C. from an unmodified 50/50 atm % NiTi target by changing the temperature of the target during deposition of a NiTi thin film. Heating the target during deposition causes a gradual compositional variation. The SME thin film produced by this method exhibit two-way SME without an external bias force. The two-way SME effect means that the device can be repeatedly cycled by heating and cooling, changing shape with each cycle without any external bias force. However, Ti is very sensitive to impurities. Thus, for high quality actuator NiTi, vacuum pressures less than 10⁻⁸ Torr are necessary for gas and vapor such as H₂O, CO₂ and CO prior to sputtering, and the distance from the target to the substrate must be limited to a few centimeters.

### SUMMARY OF THE INVENTION

Binary, ternary and higher order alloys, such as Au:Cd, Fe:Mn:Si, Cu:Zn:Al and Cu:Ni:Al, provide systems that are capable of forming two-way shape memory effect devices at vacuum base pressures greater than 10⁻⁸ Torr. Specifically, the limited reactivity of these alloys to gaseous oxidizing and nitriding contaminants and the comparatively insensitive effect of impurities on transition temperature and other shape memory effect properties allows these alloys to be prepared even at vacuum pressures of 10⁻² Torr. In addition, the distance from the target to the substrate may be increased compared to Ni:Ti sputter deposition processes at the same vacuum pressure. Thus, larger and thicker shape memory alloy films may be produced that exhibit two-way shape memory effect.

In addition, three-dimensional elements, such as tubular thin film, coatings and arbitrary three-dimensional shapes are prepared on permanent or sacrificial scaffold materials using shape memory alloys, including binary Ni:Ti and Au:Cd and higher order alloys based on Ni:Ti, Au:Cd, Fe:Mn:Si, Cu:Zn:Al and Cu:Ni:Al. Examples of three-dimensional devices include fenestrated tubular elements, domes, dimpled spherical structures and porous foams.

### BRIEF DESCRIPTION OF THE FIGURES

For the purpose of illustrating the invention, representative embodiments are shown in the accompanying figures, it being understood that the invention is not intended to be limited to the precise arrangements and instrumentalities shown.

FIG. 1 is a graph showing the compositional sensitivity NiTi transformation temperature and the dependence of transformation temperature on Ni:Ti stoichiometry.

FIG. 2 is a graph showing the NiTi phases.

FIG. 3 is a schematic of UHV sputtering system for thin film NiTi.

FIG. 4 is a graph showing the pressure of H₂O, CO₂ and CO gases during representative sputtering runs.

FIG. 5 is a graph showing the temperature profile of the target during a cooled target sputtering run.

FIG. 6 is a graph showing the temperature profile of the target during a heated target sputtering run.

FIGS. 7(a-c) show a free standing NiTi film exhibiting the two-way shape memory effect.

FIGS. 8(a-b) show the compositional gradient of film due to gradual heating of the target accounting for the two-way SME (FIG. 8a) and (FIG. 8b) shows a tailored two-dimensional bimorph structure.

FIGS. 9(a-b) illustrate the actuator for active flow control in its heated shape (FIG. 9a) and its cooled shape (FIG. 9b).

FIG. 10 illustrates a fabricated NiTi membrane actuator in the heated shape.

FIG. 11 is a RBS of sputtered film showing the compositional gradation through the thickness of the film.

FIGS. 12(a,b) show (a) an originally planar TiNi Foil Element, and (b) a heated TiNi Foil Element that deforms into a cage to envelope a volume.

FIGS. 13(a,b) show (a) shape memory alloy thin film deposited on three-dimensional molybdenum wires and (b) a cross-section of a single wire having a film depth of 4 micrometers, using a sputter deposition process according to the present invention.

FIGS. 14(a,b) show deposition two-way of shape memory alloy on (a) exterior of rotating sacrificial cylinder and (b) interior of cylinder.

FIG. 15 shows a batch process using a plurality of rotating cylindrical substrate.

### DETAILED DESCRIPTION OF THE PREFERRED EMBODIMENTS

The present invention will now be described in detail for specific preferred embodiments of the invention. These embodiments are intended only as illustrative examples and the invention is not to be limited thereto.

A process for fabricating a shape memory alloy film, comprises coating a substrate with a thin film of shape memory alloy in an enclosure. The enclosure is capable of excluding contaminant gases that react with elements of the shape memory alloy and is purged of contaminant gases such that substantially no reaction occurs between the shape memory alloy and any remaining contaminants within the enclosure. By substantially no reaction, it is meant that any reaction between the elements of the shape memory alloy and contaminating gases is limited such that the resulting film is capable of exhibiting a two-way shape memory effect at a desired phase change temperature. For example, purging may require evacuation of the enclosure to a pressure no greater than 10⁻³ Torr, heating of the enclosure, introduction of inert gas to flush the enclosure, or a combination of these and other purging processes as are known in the art.

A source of shape memory alloy is introduced into the enclosure. Preferably, the source of shape memory alloy is comprised of elements that are insensitive to any residual contaminants in the enclosure. For example, inserting a source of shape memory alloy other than a Ni:Ti-based alloy allows an enclosure to be selected for vacuum pressures during purging of greater than 10⁻⁸. For example, the purging vacuum pressure may be in a range from 10⁻⁸ to 10⁻³ Torr. More preferably, the purging vacuum pressure is selected from 10⁻⁸ to 10⁻³ Torr. For some actuators with highly insensitive shape memory alloys, such as alloys based on Au:Cd and Fe:Mn:Si, it may be preferable to use purging pressures greater than 10⁻⁶ Torr. Preferably, the shape memory alloy comprises substantially no titanium, allowing the vacuum pressure during purging to rise.

An inert gas may be introduced into the enclosure following purging. The inert gas, such as Argon gas, is added primarily to increase the rate of deposition during sputtering of the shape memory alloy from the source of shape memory alloy. By raising the pressure within the enclosure, the inert gas may also reduce or prevent leaking of contaminant gases back into the enclosure during deposition of the shape memory alloy on the substrate.

By controlling the temperature of the source, a compositional gradient may be produced through at least a portion of the thickness of the film. Thus, the film may be capable of exhibiting a two-way shape memory effect. For example, at least a portion of the thickness of the film may undergo a phase change at a phase change temperature during heating, producing a shape memory effect. Then, upon cooling, the phase reverts back to its original phase, producing a cyclical, two-way shape memory effect. In one embodiment, the temperature of the source is gradually increased from an initial temperature during the deposition of the shape memory alloy. In an alternative embodiment, the temperature is decreased during deposition. Regardless, the change in temperature creates a compositional gradient in at least a portion of the film thickness.

The substrate may be a permanent substrate or may be a sacrificial or removable substrate. For example, lithography may be used to selectively remove portions of the substrate to allow a portion of the thin film to serve as an actuator. In one embodiment, a sacrificial scaffold structure or a removable scaffold structure is used as the substrate. By eliminating the scaffold structure, a film having a three-dimensional structure may be produced, such as a porous foam, a tubular structure, a fenestrated tubular structure, a dome and/or a dimpled sphere. In one example, the substrate is cylindrical, such as a molybdenum wire, producing a tubular film. By rotationally adjusting the cylindrical substrates during deposition of the shape memory alloy, a substantially uniform film may be deposited on the cylinder. By substantially uniform, it is meant that the shape memory properties of the film are rotationally symmetric about the cylindrical axis. A substantially uniform film may be deposited along the length of the cylindrical substrate, as well. In this case, substantially uniform means that the shape memory properties do not vary by more than 2 degrees centigrade from one end of the annular film to the opposite end of the annular film. For example, a distance from the source to the substrate for a high quality, actuator grade material should be less than 6 inches. In one specific embodiment the distance of the source to the substrate is greater than 2 cm and no greater than 24 cm, for example.

In one embodiment, a shape memory effect actuator is fabricated, comprising a film of shape memory alloy having substantially no titanium. The film has a compositional gradient through at least a portion of the film thickness such that a phase change occurs above a phase change temperature, and the phase change activates a two-way shape memory effect. For example, a bubble membrane extends when heated above the phase change temperature and flattens when cooled below the phase change temperature. In another example, the actuator has at least one linear element, and the linear elements exhibit two-way shape memory effect upon heating and cooling.

In a preferred embodiment, a shape memory effect actuator comprises a shape memory alloy film having a three-dimensional shape. An operable portion of the film is capable of a two-way shape memory effect. Preferably, the operable portion of the film has a uniform film thickness and a compositional gradient through at least a portion of the uniform film thickness such that a phase change occurs at a desired phase change temperature, such as a phase change temperature at or above typical room temperature. Thus, heating above the phase change temperature and cooling below the phase change temperature is capable of activating the two-way shape memory effect without the use of any biasing mechanism, such as an external spring or a second shape memory alloy film.

Sputtering from a multi-alloy target produces a film with a composition slightly different than that of the target alloy. Heating a target causes the composition of a deposited film to more closely match the composition of the target compared to a target maintained at a lower temperature. A modified sputtering gun may control the target temperature. Therefore, target materials sputtered using the modified gun may control composition of the deposited film.

The correlation between target temperature and composition is used to produce a compositional gradient in the film through the thickness of the film. Changing the temperature of the target allows compositional gradients to produce bimorphic films, such as films having both an austenitic phase and a martensitic phase, depending on location across the thickness of the film. This compositionally graded film is seamless, and exhibits two-way shape memory effect. The two-way shape memory effect results directly from deposition without need of thermal post-treatments, such as annealing. Cyclic actuator material for microdevices is produced; the shape memory effect is capable of being repeatedly cycled merely by heating and cooling the device without application of any external bias force. This greatly simplifies device manufacturing.

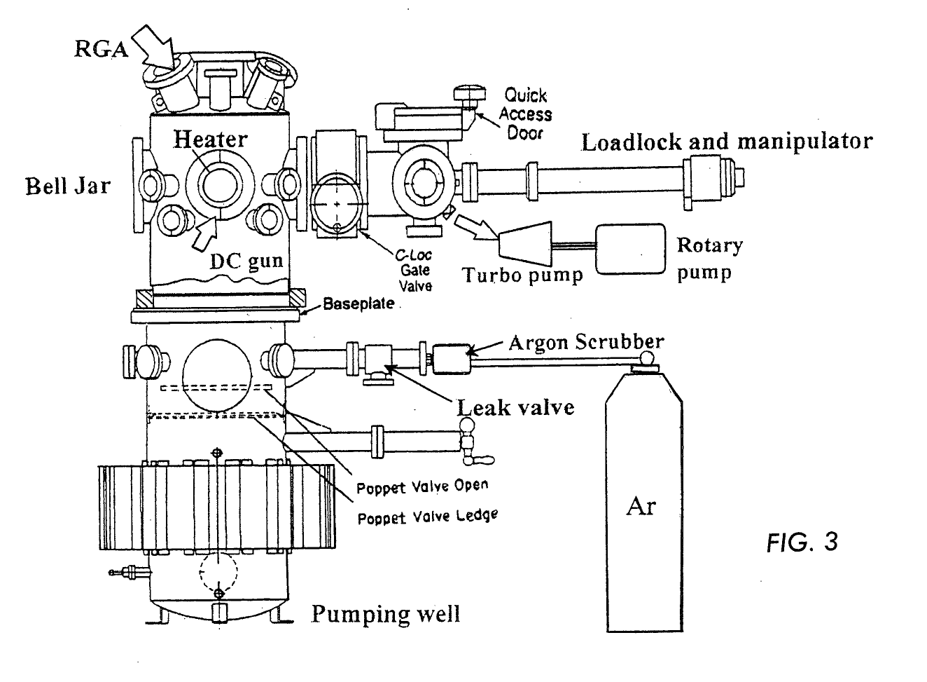

In a representative embodiment of the present invention, a sputtering system was fabricated to deposit NiTi thin films on substrates. The system was designed to be ultra clean and free from contamination during processing. A picture and schematic of the system is shown in FIG. 3. The system is UHV (ultra high vacuum) compatible with a loadlock to decrease pump down time as well as eliminate contamination. A Stanford Research Systems residual gas analyzer (RGA) was present to monitor contamination levels, particularly oxygen and water pressure, prior to sputtering. An argon scrubber was used to further clean the 99.999% purity argon gas. Sputtering was done with a 3″ DC magnetron gun from US Thin Film Products Inc. An in-situ heater with rotation capability was used to crystallize the films. The target was cut from a 3″ diameter boule of nearly stoichiometric Ni:Ti purchased from Special Metals.

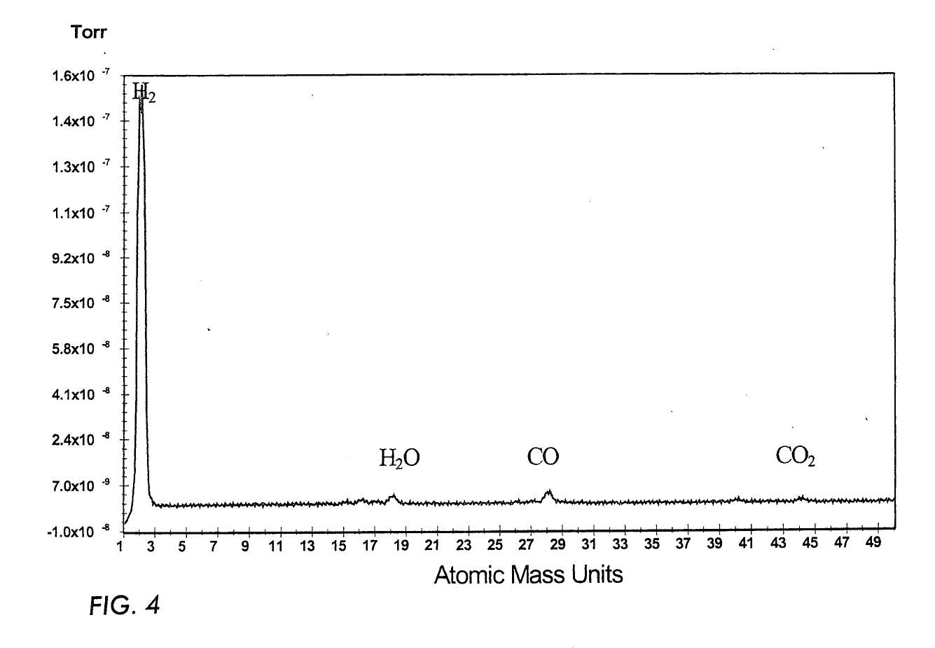

In this embodiment of the invention, prior to each run, residual gas measurement were taken with the RGA to measure the amount of contamination. Initial RGS scans prior to bakeout of the vacuum system, indicate that H₂, H₂O, CO₂, N₂ and CO were the primary gases in the system. Because of the highly reactive nature of Ti these gases can deplete the amount of Ti reaching the substrate. For this reason, H₂, N₂, H₂O, CO₂ and CO gases must be kept below 10⁻⁸ Torr (FIG. 4) for all sputtering runs using Ti as an alloy element.

In one embodiment of the invention, a shape memory alloy film was deposited using the following parameters: base pressures less than 5×10⁻⁸ Torr, P_{Ar}=2.0 mTorr, target substrate distance=3 cm-4 cm, and power=300 W. The films of Ni:Ti were crystallized by heating the substrate to greater than about 500° C. and holding it at this temperature for about 10 minutes in situ prior to removal from the sputtering system. Deposition rates at these conditions were approximately 225 nm/min as determined from film thickness measurements using a profilometer. The mean free path for molecular collision is given by the following equation:

$$λ = \frac{kT}{\sqrt{2} P {πσ}^{2}} \qquad ( 1 )$$

where k is the Boltzmann's constant, T is the absolute temperature, P is pressure, å is molecular diameter which is roughly 10⁻⁸ cm for gases [L. G. Carpenter: Vacuum Technology An Introduction (Adam Hilger Lrd, Bristol 2nd Edition, (1982))]. Table I lists the mean free path calculated from equation 1, at different pressures. The H₂O, CO₂ and CO gas pressures prior to sputtering are below 10⁻⁸ Torr, which corresponds to a mean free path of greater than about 7 cm. Thus, with a target substrate distance of 4.0 cm, there is negligible molecular interaction between the Ti and impurities that would form Ti-oxides. Also, since Ti does not react appreciably with H₂ and Ar, there should be negligible Ti loss due to gettering effects as the material is sputtered. However, by slightly increasing the pressure of these gases to 5×10⁻⁸ Torr, mean free path reduces to 1.4 cm. Now, molecular collisions between Ti and the gases would cause Ti depletion.

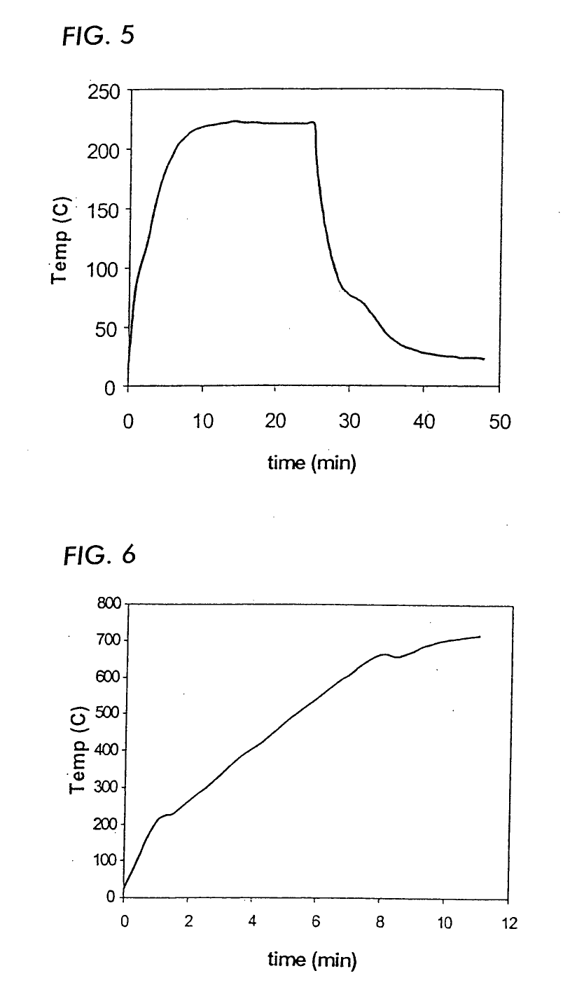

Sample C was produced by sputter deposition from a cold Ni:Ti target at a temperature initially less than 100° C. The target was cooled by thermal contact with a copper chill block. The target temperature, as measured using a thermocouple, stabilized at 225° C. during sputtering (FIG. 5).

The target temperature of Sample T was increased during sputtering from a low temperature to a high temperature, as shown in FIG. 6. The temperature of the target was increased to greater than 700° C. during deposition of a Ni:Ti film. The higher temperature was achieved by reducing or eliminating the thermally conductive paste between the target and the copper chill block, producing a thermal barrier to conduction of heat into the chill block.

The temperature of the Ni:Ti target of Sample H was initially increased to greater than about 400° C. before deposition on the substrate. This was achieved by masking or shielding the substrate during an initial warming of the target. In one embodiment, the initial warming took about 4 minutes. Then, the substrate was exposed, and sputter deposition on the substrate commenced.

The thickness of the C and T films, using a profilometer, were found to be approximately 2.5 μm thick. The H sample was only about 0.9 μm thick. The temperature profile of the hot target as a function of sputtering time is presented in Table II.

After deposition, Sample C was shiny and crystallized, indicating a high modulus austenite phase. However, Sample H was cloudy when cooled and shiny when heated. Sputtered films have tensile residual stresses such that when the NiTi film is in the martensitic phase it accommodates these stresses by twinning, thus its surface is more textured and therefore appears cloudy. Test results confirmed that at room temperature Sample C was austenite and Sample H was martensite.

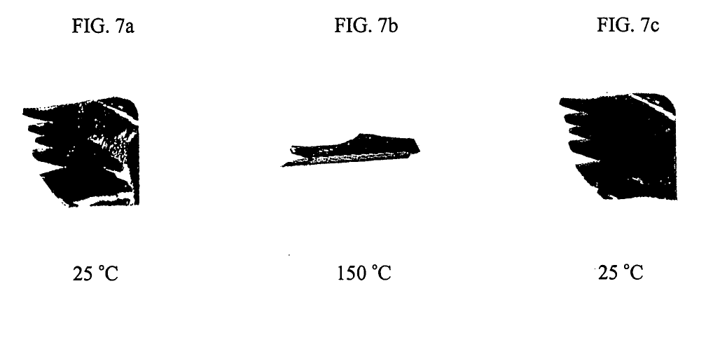

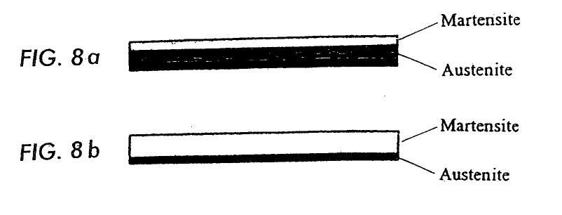

The Sample H films exhibited a two-way shape-memory effect. The resulting two-way effect is intrinsic and does not require further heat treatments. FIGS. 7(a-c) show the film at three stages: 25° C., 150° C., and back to 25° C. Without external biasing of the film, the film is initially flat, curled when heated and uncurled when cooled back to room temperature. We attribute this to the fact that the film has a compositional gradient through its thickness. Although the invention is not limited by this interpretation, the inventors believe that a lower portion of the film is austenite and a top portion is martensite, creating a superelastic system combined with a shape memory system (FIG. 8a). As the target temperature increases during deposition, compositional changes in the film cause a transition from an austenitic phase to a martensitic phase. Upon heating of the film, the upper martensite transforms to austenite, causing the film to curl. When subsequently cooled the stresses induced by the thin austenite layer are sufficient to twin the martensite and flatten the film. In another example, the two-way effect was used to fabricate a MEMS bubble actuator.

The Sample T also exhibited a two-way memory effect, without further heat treatments, see FIGS. 7(a-c). Without any external biasing, the film initially flat, curled when heated and uncurled when cooled back to room temperature.

Control of the target temperature provides for fabrication of a two-dimensional austenite-martensite bimorph (FIG. 8b). In addition, the proportion of austenite to martensite can be tailored, resulting in a predefined force-displacement response.

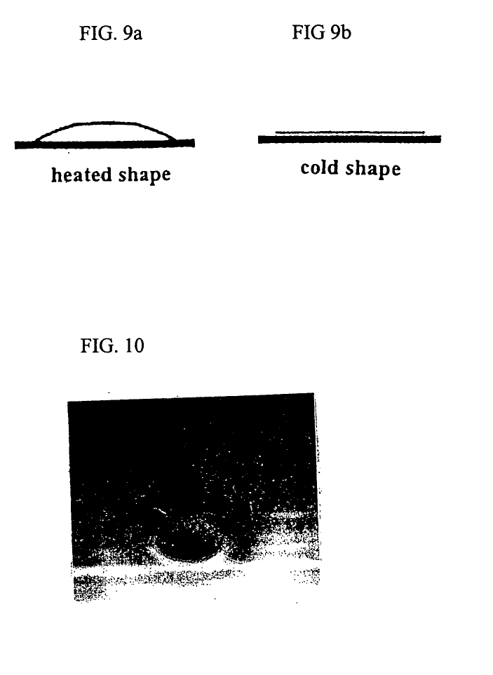

One embodiment of the present invention is as a microscale actuator for active flow control (AFC) using a bubble membrane (FIG. 9). Upon heated, such as by resistance heating, the membrane actuator extends into the flow field. When subsequently cooled the membrane flattens out. Thus, the membrane may be configured as an actuator exhibiting a two-way effect. Although the actuator was designed for possible use in active flow control, the simplicity of the device will allow it to be adapted as an actuator for many other devices, such as micropumps, microvalves, and micro switches. The inventors fabricated a 3 mm diameter NiTi membrane actuator capable of 500 μm of vertical deflection for use in microscale actuated flow control (FIG. 10). The same membrane actuator can be used in microdevices such as micropumps, and microvalves.

Resistivity of the bulk target and the film samples were measured with the four point probe at room temperature. The resistivity for a bulk material and a thin film are given by the following equations respectively:

$$ρ = 2 π s ( \frac{V}{I} ) \qquad ( 2 )$$

where V, is voltage, I current, s probe spacing, and t film thickness. The resistivity

$$ρ = \frac{π t}{1 n 2} ( \frac{V}{I} ) \qquad ( 3 )$$

of the target was found to be 65 μohm-cm at 25° C. Resistivity for the C sample, T sample and H sample at 25° C. were 93, 86, and 75 μohm-cm respectively.

Compositional analysis of the target and sputtered films were done with RBS. Samples were taken from the center of each wafer. RBS is reported to be accurate to within 0.5 atm %. Results were summarized in table V. The composition of the target was 51.8 atm % Ti:Ni, the T sample composition was 50.5 atm % Ti, and the C sample had a composition of 49.2 atm % Ti. The H sample had a composition slightly closer to that of the target than the T sample 50.8 atm % Ti. Assuming that temperature influences Ti composition, this would be expected as the H sample was deposited from a target that was always above 450° C. whereas the target temperature was ramped up from 25° C. for the T sample. We believe these results confirm our assumption that heating the target alters the composition of the deposited films. In this case the heated target produced films with composition very near that of the target.

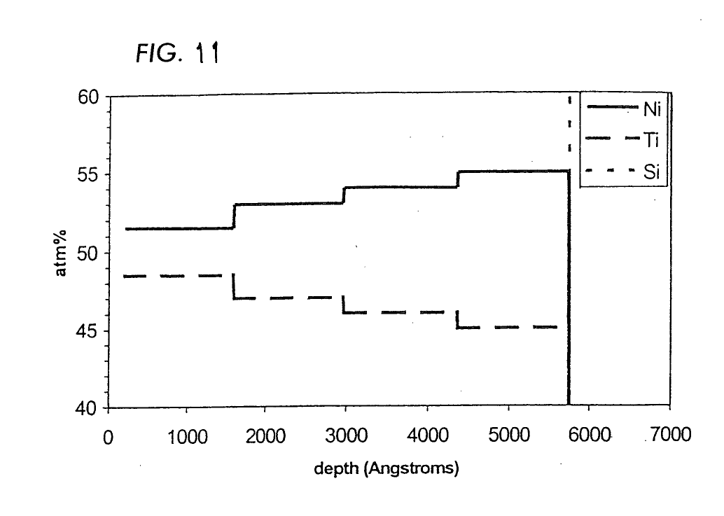

As mentioned in the experimental setup, T films were sputtered at temperatures transitioning from room temperature up to 700° C. As the target heats up, the film produced should have a compositional gradation through its thickness. RBS can give composition through the thickness of a film if the film is sufficiently thin, such that the RBS signal penetrates through the film and detects the substrate reference (<1 μm). To obtain films thin enough for observing compositional variation through the thickness, the T sample film was divided into thinner sections by sputtering for 4 minutes then rotating the substrate to sputter the remaining 6 minutes on a new location. The initial 4 minutes of sputtering, which corresponds to a maximum temperature of 400° C. were examined. The composition versus depth is given in FIG. 11.

These results show that the Ni content decreases through the thickness corresponding to an increase in target temperature. The initial 0.1 μm thickness at the beginning of the deposition run shows a Ti composition of 45.0 atm % Ti which is a fairly large deviation from the target composition. At the top, the film composition is closer to the composition of the target at 48.5 atm % Ti. This compositional gradient occurs over too large a thickness range 0.6 μm to be attributed to interfacial reactions, which have been shown to be limited to film thicknesses of 10-100 nm in thickness [Q. Su, S. Z. Hua, M. Wuttig, SPIE 2189, 409 (1994)].

Without limiting the invention, the authors believe that the difference in film properties is caused by the change in target temperature during deposition. Ti has a higher sputtering yield; however, the flux of Ni and Ti from the target must conserve mass, resulting in a change in the surface layer about 800 Å thick on the target that is richer in Ni. The precise composition is such that both the difference in sputtering yield and an equal atomic flux of Ni and Ti are accommodated. Although the flux of Ni and Ti atoms from target is the same, films deposited by sputtering typically do not have the same composition as the target. This difference in film composition may be visualized as resulting from two factors: a difference in angular distribution and sticking coefficient of the sputtered species. It has been shown that the polar angular distribution of Ti is wider than that of Ni during sputtering [V. S. Chemysh, V. S. Tuboltsev, V. S. Kulikauskas: Nuclear Instr. And Methods in Physics Research B 140, 303 (1998) and I. Neshev, R. G. Vichev, S. Tzanev, S. S. Todorov: Vacuum 44, No. 3-4, 209 (1993)]. This means that the Ti:Ni ratio is larger at low angles from the target surface plane and is smaller at 90° from the surface plane. Also, this difference in angular distribution becomes more pronounced and further the substrate is from the target. We believe that the angular distribution difference is caused by the altered composition of the surface layer of the target.

Now, heating of the target to high temperatures decreases the binding energy, changing the sputtering yields of Ni and Ti, which changes the composition of the surface layer. Diffusion may also be a factor at high temperatures influencing the composition of the surface layer. The surface layer of the target is altered by heating the target, resulting in a change in the distribution of Ni and Ti such that the difference becomes less pronounced. Thus, the composition of the sputtered shape memory alloy more closely resembles the composition of the target.

SME above 25° C. is difficult to produce, especially for Ni:Ti, which has shape memory characteristics that are very sensitive to composition. As a consequence, sputter deposition from a single near equiatomic NiTi target typically requires compensation with additional titanium plates. Ni:Ti shape memory alloys targets that are heated above 400° C. before commencing deposition result in films having shape memory effect above 25° C. Controlling the target temperature can also be used to produce films with the two-way SME. This novel method of fabricating two-way SME is improved using new SME alloys that are less sensitive to impurities.

A. Peter Jardine, “Deposition parameters for sputter-deposited thin film TiNi”, Mat Res. Soc. Symp. Proc., Vol 360, 1995, discloses practical limitations imposed by a vacuum system for the relationship between base vacuum pressure and target-sample distance, which affects the phases in sputter deposited Ti—Ni thin films.

For a Pᵣ value of 0.01 [1% Ni shift], representing the lower limit, at a [sample-target] distance of 6.0 cm the base pressure was 5×10⁻⁷ torr. Using a more reasonable value of P=0.001, corresponding to a stoichiometric deviation of 0.1 at %, a minimum pressure of 8×10⁻⁸ torr is required. These values are in agreement with the observations of many workers that a pressure of 10⁻⁷ torr was needed to obtain stoichiometric TiNi. At larger distances of 15.2 cm (6 in), the requisite base pressure was approximately 2×10⁻⁸ torr for P=0.01 and 2×10⁹ torr for P=0.001 . . . .

X-ray diffraction profiles [for a base pressure of 2×10⁻⁸ and a target to sample] . . . distance of 8.0 cm . . . shows two peaks, corresponding to the TiNi's B2 [100] peak at . . . (2.12 Å) [an austenitic phase] and a peak at . . . (2.09 Å) possibly the B 19 [020] peak [a martenistic phase] . . . .

At 10cm to 20 cm, the B2 peak is observed, indicating low martensitic transformation temperatures [below room temperature]. At 25 cm, B2 peak is difficult to identify and . . . had additional peaks corresponding to the likely formation of oxides and nitrides on the surface . . . .

For successful deposition of TiNi . . . at a distance of 10 cm (4 in), the maximum base pressures that can be tolerated [and still have a martensitic phase present above room temperature] are of the order of 10⁻⁹ torr . . . . The extreme composition dependence of the SME properties of TiNi suggests that sputtering distances and base pressures are important to ensure that the resultant transformations will be uniformly similar for TiNi devices made from a wafer, regardless of the position of the material on the substrate.

Miyazaki and K. Nomura, “Development of perfect shape memory effect in sputter-deposited Ti—Ni thin films”, Proceedings IEEE Microelectro Mechanical Sys., p. 176, 1994 discloses that shape recovery stress and shape recovery strain were large enough for fabricating microactuators to power micromachines.

The shape recovery stress [of a Ti—Ni shape memory alloy thin film] was more than 400 MPa. The maximum shape recovery strain amounted to 3% [for perfect shape memory effect] . . . . The maximum recovery stress amounted to as much as 600 MPa.

R. H. Wolf and A. H. Heuer, “TiNi (Shape Memory) Films on Silicon for MEMS Applications”. J. of Microelectromechanical Sys., vol.4, no.4, p.206, 1995 discloses a method for fabricating a TiNi diaphragm from a TiNi shape memory alloy in thin film form that is an excellent candidate for a MEMS micro-actuator.

The diaphragms recovered greater than 2% strain when heated through the phase transformation temperature, providing a . . . work density of at least 5×10⁶ J/m³. This work density is higher than that of any other type of microactuator . . . .

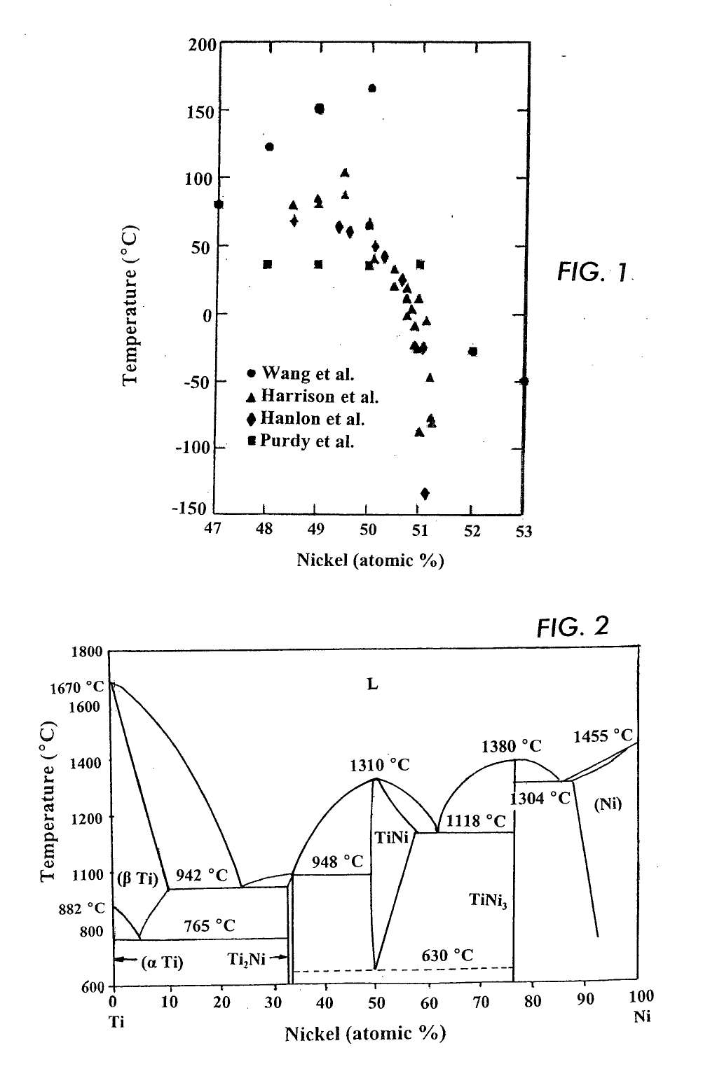

For the fabrication of TiNi diaphragms, substrate micromachining was done prior to deposition, in order to minimize the exposure of the TiNi to hot ethylene diamine pyrocatechol (EDP) etchant. Wafers with a thermal oxide on both sides were coated with photoresist and “soft baked.” The photoresist was then patterned on the back side to open EDP etch windows in the oxide. This pattern contained 2 mm×2 mm square diaphragms and division lines separating the wafer into individual 10 mm×10 mm diaphragm sections. EDP was then used to etch a majority of the diaphragm cavities, as well as the division lines. The oxide was removed from the front side of the wafer just prior to deposition using a buffered oxide etchant. After the TiNi was deposited and annealed, the remainder of the silicon diaphragm support was removed using EDP, thus releasing a suspended diaphragm of TiNi (FIG. 1).

P. Krulevitch, A. P. Lee, P. B. Ramsey, et.al., “Thin film shape memory alloy microactuators”, J. of Microelectromechanical Sys., vol.5, no.4, 1996 discloses micromachining and design issues for SMA micro-actuators.

TiNi Alloy Co. built a membrane-based gas microvalve that survived more than two million cycles, and along with Microflow Analytical Inc., they have made microvalves with SMA ligaments serving as the actuator . . . . Nickel-titanium-copper SMA's with 50 at. % Ti and 5-15 at. % Cu, are less sensitive to composition than binary Ni—Ti, making Ni—Ti—Cu films a more forgiving material for thin film deposition . . . . Typical sputtering pressures range from 0.1 to 0.93 Pa . . . . A bimorph-type SMA diaphragm deflects downwards upon heating, pulling away from the glass cover layer and opening the valve. After etching the flow channels on the front side, the diaphragm region was etched from behind using the anisotropic silicon etchant ethylene diamine pyrocatechol (EDP), forming a 2.0 μn boron-doped silicon diaphragm. A 1.5-μm thick Ni—Ti—Cu film was then deposited onto the back side of the diaphragm. Next, a 100-nm gold film with a 5-nm titanium adhesion layer was evaporated over the silicon diaphragm region to prevent adhesion of the diaphragm to the glass during the low temperature (300° C.) anodic bonding step. Exposure to nitrogen for approximately two hours at 300° C. during the bonding caused the surface of the Ni—Ti—Cu film to nitridize, giving the originally silver colored film a golden hue, and reduced the recoverable stress from 340 to 308 MPa.

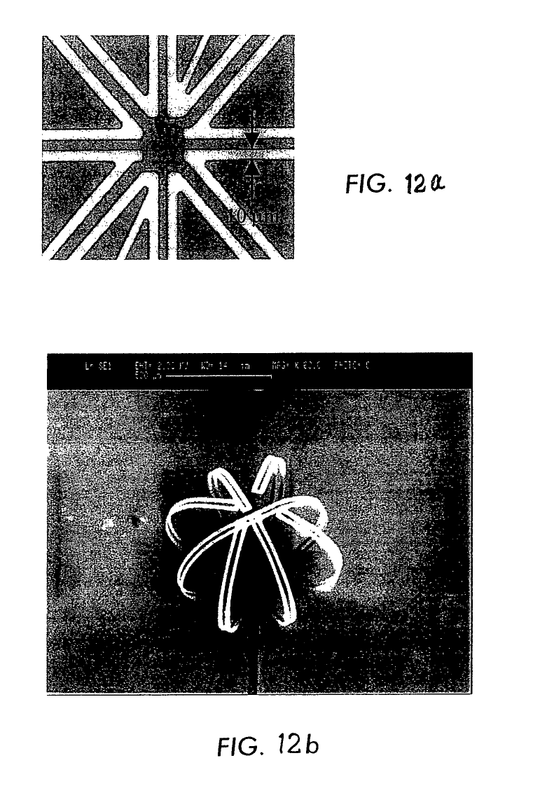

FIG. 12 shows a shape memory effect device comprising a thin film foil elements. The elements were produced by increasing the temperature of the target during sputter deposition onto a substrate. The elements have a compositional gradation, having one surface of the film with a martensitic phase at room temperature, while the other surface is an austenitic phase. Upon heating above the transition temperature, which is above room temperature, the martensite changes phase to austenite, resulting in the curling of the elements into the shape of a spherical cage. Upon cooling to room temperature, the martensitic phase returns, and the elements return to a planar configuration.

In one example, a heated target facilitates sputter deposition of a gold cadmium shape memory alloy film. One advantage of a AuCd over nickel titanium is that the AuCd system is much less sensitive to contaminants such as oxygen, water vapor and nitrogen. Thus, the base pressure may be greater than 10⁻⁸ Torr, the distance between the target of a substrate for two-way shape memory effect actuator grade material may be up to 6 inches and a two-way shape memory effect film may be thicker than a comparable film for nickel titanium. For example, AuCd may be alloyed with an additional element to form a ternary shape memory alloy, using hydrogen, copper, silver, zinc or mercury as the third alloying element. Alternatively, higher order alloys may comprise more than one of the elements. The target temperature during deposition is selected in a range from 150° C. to 400° C. and the substrate temperature is maintained between one-third and two-thirds of the alloy melting temperature, for example. The melting temperature for AuCd-based ternary alloys ranges from about 190° C. to 400° C. Preferably, the vacuum pressure during sputter deposition is selected in a range from 9×10⁻⁴ Torr to 1×10⁻² Torr by adding an inert gas. The rate of deposition increases as the amount inert gas increases. The limited reactivity of Au and Cd to contaminants such as oxygen, water and nitrogen allows a comparatively high vacuum base pressure during purging of the contaminants, which may be selected at a vacuum pressure no greater than 10⁻³ Torr. For example, a range from 10⁻⁶ Torr to 10⁻³ Torr is preferred for the base pressure during purging prior to introduction of the inert gas. By limiting the base pressure to 10⁻⁶ Torr, the design of the enclosure is greatly simplified compared to ultra high vacuum system required for Ni:Ti SMA. This allows commercial production of much larger devices.

In another example, the shape memory alloy is selected from an iron manganese silicon quaternary or higher order alloy wherein additional alloying elements are selected from hydrogen, boron, carbon, magnesium, aluminum, silicon, phosphorous, sulfur, calcium, scandium, titanium, vanadium, chromium, colombium, nickel, copper, zinc, selenium, strontium, yttrium, zirconium, niobium, molybdenum, ruthenium, rhodium, palladium, silver, cadmium, tin, antimony, tellurium, barium, lanthanum, hafnium, tantalum, tungsten, rhenium, osmium, iridium, platinum, gold, lead, bismuth, polonium, cerium, praseodymium, neodymium, samarium, europium, gadolinium, terbium, ytterbium, lutetium, thorium, protactinium, and uranium. The target temperature is selected to be at least 770° C., and the process temperature of the substrate is selected to be in a range from about one-third to two-thirds of the melting temperature of the quaternary or higher order alloy composition, for example. The melting temperature for the alloys considered here ranges from about 1,100° C. to 1,400° C. The vacuum pressures during processing are selected in a range from 9×10⁻⁴ Torr to 10⁻² Torr and an inert gas is used to generate a plasma. Iron, manganese and silicon have limited reactivity to the typical contaminants such as oxygen, water and nitrogen. For actuator grade material having a two-way shape memory effect, the base pressure during purging should be selected at a pressure no greater than 10⁻⁵ Torr.

In yet another example, the shape memory alloy is based on one of copper zinc aluminum and copper nickel aluminum. Specifically, ternary, quaternary and higher alloys are used including hydrogen, boron, carbon, magnesium, aluminum, silicon, phosphorous, sulfur, calcium, scandium, titanium, vanadium, chromium, colombium, nickel, copper, zinc, selenium, strontium, yttrium, zirconium, niobium, molybdenum, ruthenium, rhodium, palladium, silver, cadmium, tin, antimony, tellurium, barium, lanthanum, hafnium, tantalum, tungsten, rhenium, osmium, iridium, platinum, gold, lead, bismuth, polonium, cerium, praseodymium, neodymium, samarium, europium, gadolinium, terbium, ytterbium, lutetium, thorium, protactinium, and uranium. For example, the target temperature is selected in a range from at least 350° C. The process temperature of the substrate is maintained in a range from about 190° C. to 400° C., for example. The vacuum pressure during processing is selected to be in a range from 9×10⁻⁴ Torr to 10⁻² Torr, using an inert gas to generate a plasma. In this example, the element aluminum is even more reactive than titanium to some of the typical contaminants such as oxygen, water and nitrogen; however, the degree of sensitivity of the transition temperatures and other material properties of the shape memory alloy are substantially less than for titanium in Ni:Ti SMA. Thus, a base pressure during purging of contaminants may be selected that is no greater than 10⁻⁶ Torr for actuator grade, two-way shape memory alloys.

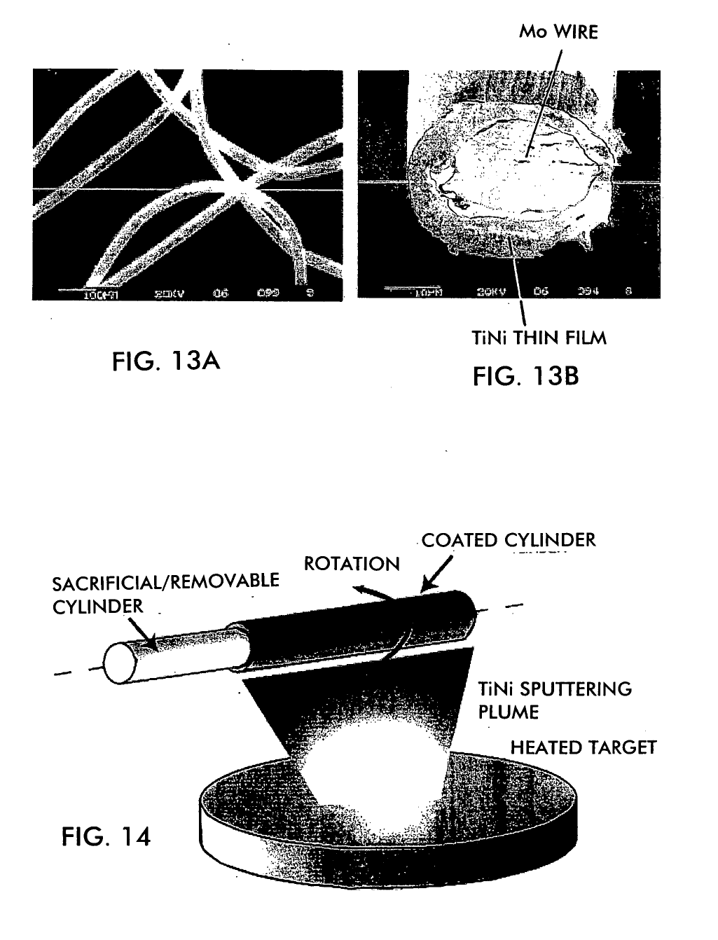

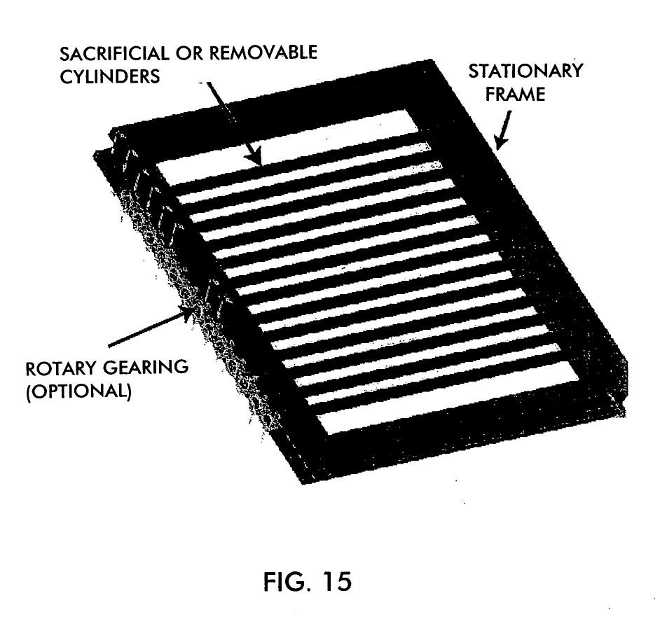

Complex three-dimensional shapes are manufactured using permanent, removable or sacrificial substrates. For example, three-dimensional, thin film tubes are prepared by depositing a film of shape memory alloy on a scaffold material, such as a metal, a ceramic or a polymer material. FIG. 13(a) shows a three-dimensional wire weave, which is coated by a thin film of two-way shape memory alloy using sputter deposition. For example, a Ni:Ti thin film surrounds a molybdenum wire that served as a permanent substrate for deposition of the titanium nitride thin film. Alternatively, the shape memory alloy film may be deposited on other three-dimensional structures, such as a porous foam substrate. For example, the shape memory effect coating may offer the porous foam a means of actuation or mechanical damping. As shown in FIG. 1b, a Ni:Ti film was deposited having a thickness of about 4 microns. In one embodiment, rotation of the substrate improves uniformity of the coating, providing a coating with a substantially uniform thickness surrounding the substrate around the axis rotation. For example, by depositing a film of a shape memory alloy onto a rotating, removable or sacrificial cylinder element, a seamless, thin-walled tube may be prepared, as illustrated in FIG. 2. In order to prepare a two-way, shape memory alloy thin film, the target is heated during sputtering of the shape memory alloy. The rate of rotation of the cylindrical substrate, the rate of temperature change of the heated target and the rate of deposition are controlled, such that a compositional gradient extends through the thickness of the annular coating. In one embodiment, the processing conditions are controlled such that the shape memory effect and material properties are substantially uniform from one end of the tube to the opposite end of the tube. By substantially uniform, it is meant that the properties do not vary by more than 2° C., which permits the development of large scale batch manufacturing of shape memory alloy tube.

For example, FIG. 3 illustrates a device for mass producing thin-walled shape memory alloy tubes. A frame supports sacrificial or removable cylinders by optional rotating gear mechanisms. By sputtering shape memory alloy on the cylinders while the cylinders are being rotated, seamless shape memory alloy tubes are produced.

Although the foregoing invention has been described in some detail by way of illustration and example for purposes of clarity and understanding, it will be obvious that various modifications and changes which are within the knowledge of those skilled in the art are considered to fall within the scope of disclosed invention.

TABLE I
mean free path at varying pressures for Ni:Ti two-way SMA film

| Pressure (Torr) | Mean free path (cm) |
|---|---|
| 1 × 10⁻⁶ | 0.07 |
| 1 × 10⁻⁷ | 0.7 |
| 5 × 10⁻⁸ | 1.4 |
| 1 × 10⁻⁸ | 7.0 |
| 1 × 10⁻⁹ | 70 |

TABLE II

| Time (min) | Temp (° C.) |
|---|---|
| 0 | 30 |
| 5 | 310 |
| 10 | 540 |
| 15 | 650 |

TABLE II
DSC Results

| Sample | As | Af | Ms | Mf |
|---|---|---|---|---|
| Target (from | 95° C. | 110° C. | 68° C. | 55° C. |
| manufacturer) | | | | |
| H sample | 80° C. | 105° C. | 60° C. | 20° C. |
| (Hot target) | | | | |
| C sample | −7° C. | 22° C. | −100° C. | −150° C. |
| (Cold target) | | | | |

TABLE III
DSC Results

| Sample | As | Af | Ms | Mf |
|---|---|---|---|---|
| Target (from manufacturer) | 70° C. | 100° C. | 65° C. | 35° C. |
| T sample (Heated target) | 75° C. | 95° C. | 60° C. | 30° C. |
| C sample (Cold target) | 10° C. | 25° C. | −25° C. | <−100° C. |

TABLE IV
4-point probe Results

| Sample | As | Af | Ms | Mf |
|---|---|---|---|---|
| Target (from manufacturer) | 90° C. | 100° C. | 60° C. | 40° C. |
| T sample (Heated target) | 95° C. | 95° C. | 55° C. | 25° C. |
| H sample (Cold target) | 90° C. | 95° C. | 55° C. | 25° C. |

TABLE V
RBS results

| Sample | Ni at. % | Ti atm % | Ni:Ti Ratio |
|---|---|---|---|
| C sample | 50.8 | 49.2 | 1.03 |
| T sample | 49.5 | 50.5 | 0.98 |
| H sample | 49.2 | 50.8 | 0.969 |
| Target | 48.2 | 51.8 | 0.931 |

What is claimed is:

1. A process for fabricating a shape memory alloy film, comprising:
inserting a substrate in an enclosure;
introducing a source of a shape memory alloy other than a Ni:Ti-based alloy into the enclosure;
purging the enclosure such that substantially no reaction occurs between the shape memory alloy and the contaminants remaining within the enclosure after purging;
introducing an inert gas such that the pressure within the enclosure is raised;
setting an initial temperature of the source;
depositing a film of shape memory alloy from the source onto the substrate;
controlling the temperature of the source such that the composition of the film has a compositional gradient through at least a portion of the thickness of the film, wherein the film is capable of exhibiting a two-way shape memory effect.

2. The process of claim 1, wherein the substrate is one of a sacrificial scaffold structure or a removable scaffold structure and further comprising a step of eliminating the scaffold structure such that the film has a three-dimensional structure.

3. The process of claim 1, wherein purging the enclosure includes evacuating the enclosure, wherein the vacuum pressure during evacuating is selected in a range greater than 10⁻⁸ Torr and no greater than 10⁻³ Torr.

4. The process of claim 3, further comprising selecting a shape memory alloy for the source from the group of shape memory alloys consisting of Au:Cd, Fe:Mn:Si, Cu:Zn:Al, Cu:Ni:Al and higher order alloys based thereon.

5. The process of claim 4, wherein the shape memory alloy is of Au:Cd or is a higher order alloy based on Au:Cd.

6. The process of claim 4, wherein the shape memory alloy is of Fe:Mn:Si or is a higher order alloy based on Fe:Mn:Si, and the range of vacuum pressure is no greater than 10⁻⁵ Torr.

7. The process of claim 4, wherein the shape memory alloy is of Cu:Zn:Al or is a higher order alloy based on Cu:Zn:Al, and the range of vacuum pressure is no greater than 10⁻⁶ Torr.

8. The process of claim 4, wherein the shape memory alloy is of Cu:Ni:Al or is a higher order alloy based on Cu:Ni:Al, and the range of vacuum pressure is no greater than 10⁻⁶ Torr.

9. The process of claim 3, wherein the step of controlling the temperature increases the temperature of the source gradually over time during deposition of the film.

10. The process of claim 3, wherein the distance between the source and the substrate is greater than 2 cm and no greater than 24 cm.

11. The process of claim 3, wherein the substrate is tubular, further comprising a step of rotationally adjusting the orientation of the substrate such that the film thickness is radially uniform about the rotational axis.

12. A shape memory effect actuator, comprising:
a film comprising a shape memory alloy having substantially no titanium, the film having a film thickness and a compositional gradient through at least a portion of the film thickness such that a phase change occurs above a phase change temperature, wherein the phase change activates a two-way shape memory effect.

13. The actuator of claim 12, wherein the actuator is a bubble membrane, the bubble membrane extending when heated above the phase change temperature and flattening when cooled below the phase change temperature.

14. The actuator of claim 12, wherein the film comprises at least one linear element such that the at least one linear element is capable of activating a two-way shape memory effect.

15. A shape memory effect actuator, comprising:
a film having a three-dimensional shape and comprised of a shape memory alloy, at least an operable portion of the film being capable of a two-way shape memory effect, the operable portion of the film having a uniform film thickness and a compositional gradient through at least a portion of the uniform film thickness such that a phase change occurs at a phase change temperature, and the phase change is capable of activating a two-way shape memory effect.

16. The actuator of claim 15, wherein the three-dimensional shape of the film comprises a fenestrated tubular element.

17. The actuator of claim 15, wherein the three-dimensional shape of the film comprises a porous foam.

18. The actuator of claim 15, wherein the three-dimensional shape of the film comprises a dimpled spherical structure.

19. A film of shape memory alloy having substantially no titanium and comprising a compositional gradient through at least a portion of the film such that a phase change occurs above room temperature, wherein the phase change is capable of activating a two-way shape memory effect.

20. The film of claim 17, wherein the shape memory alloy is selected from one of Au:Cd, Fe:Mn:Si, Cu:Zn:Al, Cu:Ni:Al and higher order alloys based thereon.
